(19) United States
(12) Patent Application Publication
(10) Pub. No.: US 2025/0284100 A1
(43) Pub. Date: Sep. 11, 2025

(54) OPTICAL SYSTEM, IMAGING DEVICE, IN-VEHICLE SYSTEM, AND MOVABLE APPARATUS

(71) Applicant: CANON KABUSHIKI KAISHA, Tokyo (JP)

(72) Inventors: NAOTO DOUJOU, Tochigi (JP); KAZUHIKO KAJIYAMA, Tochigi (JP)

(21) Appl. No.: 19/219,855

(22) Filed: May 27, 2025

Related U.S. Application Data
(63) Continuation of application No. PCT/JP2023/041476, filed on Nov. 17, 2023.

(30) Foreign Application Priority Data
Nov. 29, 2022 (JP) 2022-190032

(51) Int. Cl. G02B 13/00; G02B 15/14; H10F 39/00

(52) U.S. Cl. CPC G02B 13/0045; G02B 15/1465; H10F 39/806

(57) ABSTRACT

An optical system includes a first negative lens having a first aspheric surface, a second negative lens, a third negative lens that is a meniscus lens whose object-side surface is concave, a first positive lens, a cemented lens, and a final lens that is disposed closest to an image plane and includes an aspheric surface, which are arranged in this order from an object side, wherein an aperture stop is disposed between the third negative lens and the first positive lens, or between the first positive lens and the cemented lens, and wherein the first aspheric surface has at least one inflection point in a cross-section including an optical axis.

### CROSS-REFERENCE TO RELATED APPLICATIONS

This application is a Continuation of International Patent Application No. PCT/JP2023/041476, filed Nov. 17, 2023, which claims the benefit of Japanese Patent Application No. 2022-190032, filed Nov. 29, 2022, both of which are hereby incorporated by reference herein in their entirety.

### BACKGROUND

### Technical Field

The present disclosure relates to an optical system that has a lens with an aspheric surface, which is suitable for an imaging device used in an in-vehicle system, a surveillance system, or the like, for example.

### Description of the Related Art

Japanese Patent Application Laid-Open No. 2007-155976 discusses an optical system with a wide angle of view using an aspherical lens. In an imaging device using a single optical system, in the case of capturing an image of an object at the center of the field of view and an object at the periphery of the field of view at the same time, it is demanded that the center of the field of view is higher in resolution than the periphery of the field of view.

### SUMMARY

According to an aspect of the present disclosure, an optical system includes a first negative lens having a first aspheric surface, a second negative lens, a third negative lens that is a meniscus lens whose object-side surface is concave, a first positive lens, a cemented lens, and a final lens that is disposed closest to an image plane and includes an aspheric surface, which are arranged in this order from an object side, wherein an aperture stop is disposed between the third negative lens and the first positive lens, or between the first positive lens and the cemented lens, and wherein the first aspheric surface has at least one inflection point in a cross-section including an optical axis.

Further features of the present invention will become apparent from the following description of exemplary embodiments with reference to the attached drawings.

### BRIEF DESCRIPTION OF THE DRAWINGS

FIG. 1 is a schematic diagram of a main part of an optical system according to Example 1.

FIG. 2 is a diagram illustrating modulation transfer function (MTF) curves of the optical system according to Example 1.

FIG. 3 is a schematic diagram of a main part of an optical system according to Example 2.

FIG. 4 is a diagram illustrating MTF curves of the optical system according to Example 2.

FIG. 5 is a schematic diagram of a main part of an optical system according to Example 3.

FIG. 6 is a diagram illustrating MTF curves of the optical system according to Example 3.

FIG. 7 is a schematic diagram of a main part of an optical system according to Example 4.

FIG. 8 is a diagram illustrating MTF curves of the optical system according to Example 4.

FIG. 9 is a schematic diagram of a main part of an optical system according to Example 5.

FIG. 10 is a diagram illustrating MTF curves of the optical system according to Example 5.

FIG. 11 is a schematic diagram of a main part of an optical system according to Example 6.

FIG. 12 is a diagram illustrating MTF curves of the optical system according to Example 6.

FIG. 13 is a diagram illustrating the local curvature of the object-side surface of a first lens in each example.

FIG. 14 is a schematic diagram of a main part of an imaging device according to an exemplary embodiment.

FIG. 15 is a schematic diagram of a movable apparatus and an imaging device held by the movable apparatus according to an exemplary embodiment.

FIG. 16 is a block diagram of an in-vehicle system according to an exemplary embodiment.

### DESCRIPTION OF THE EMBODIMENTS

Hereinafter, desirable exemplary embodiments of the present invention will be described with reference to the accompanying drawings. The drawings may be illustrated at a scale different from the actual scale for convenience. In addition, in the diagrams, the equivalent components are represented with the same reference numerals, and duplicated description thereof will be omitted.

An optical system according to an exemplary embodiment includes, in order from the object side, a first negative lens having an aspheric surface, a second negative lens, a third negative lens that is a meniscus lens whose object-side surface is concave, a first positive lens, and a cemented lens. An aperture stop is disposed between the third negative lens and the first positive lens, or between the first positive lens and the cemented lens. The aspheric surface has at least one inflection point in a cross-section including the optical axis.

The above-described structure makes it possible to provide an optical system with a wide angle of view and excellent optical characteristics.

The optical system according to the present exemplary embodiment can produce the advantageous effect by satisfying at least the above-described structure, and may have a plurality of positive lenses, four or more negative lenses, or two or more cemented lenses, for example. Each cemented lens is not limited to a pair of positive and negative lenses but may also include three or more lenses. In addition, an optical element that does not contribute to the image formation of the optical system, such as an optical filter or a cover glass, may be disposed on the image side of the lens (final lens) that is closest to the image plane among the lenses of the optical system.

### Example 1

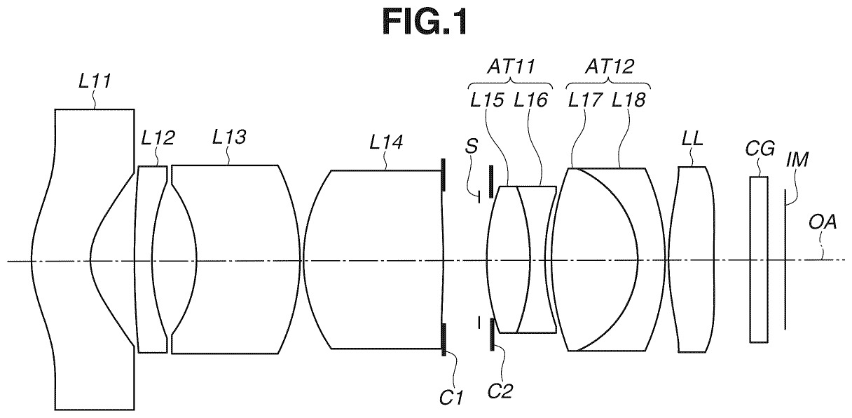

FIGS. 1, 3, 5, 7, 9, and 11 are schematic diagrams of a main part of the optical system in cross-section including the optical axis according to examples. In each diagram, the left side is the object side (front), and the right side is the image side (rear). In each diagram, the dash-dotted line indicates an optical axis OA of the optical system. The optical system in each example is an imaging optical system used in an imaging device, and the imaging surface of an imaging element is disposed at the position of an image plane IM. An optical block CG disposed on the object side of the image plane IM is an optical element that does not contribute to imaging in the optical system, such as an optical filter or a cover glass.

The optical system according to each example is an image-forming optical system that forms an image of an object (not illustrated) on the image plane IM by collecting light from the object. That is, the optical system according to each example has a positive refractive power throughout the entire system. In the case of applying the optical system according to each example to an imaging device or a distance measuring device, the light receiving surface (imaging surface) of a light receiving element (imaging element) is disposed at the position of the image plane IM.

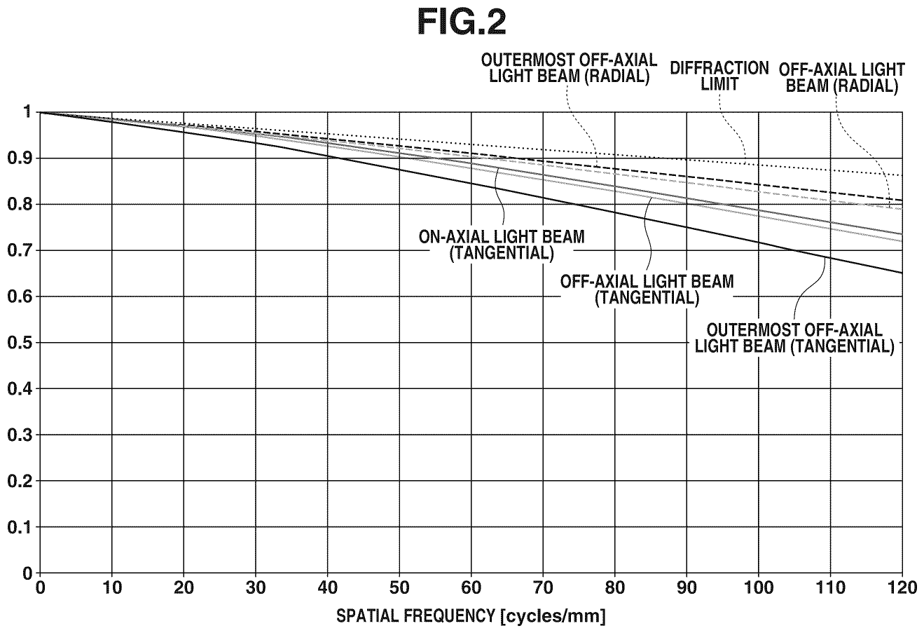

FIGS. 2, 4, 6, 8, 10, and 12 are diagrams illustrating modulated transfer function (MTF) curves of the optical systems according to the examples. In each diagram, the horizontal axis indicates spatial frequency [cycles/mm], and the vertical axis indicates MTF value (contrast value). Each diagram represents a curve indicating the diffraction limit, an MTF curve for an on-axial light beam reaching an on-axial image height (central angle of view of 0°), an MTF curve for an off-axial light beam reaching an off-axial image height corresponding to a half angle of view of 30°, and an MTF curve for an outermost off-axial light beam reaching an outermost off-axial image height (a half angle of view of 60°).

The optical system according to Example 1 will be described below.

The optical system according to the present example consists of a first negative lens L11 including an aspheric surface, a second negative lens L12, a third negative lens L13, a first positive lens L14, a first cemented lens AT11, a second cemented lens AT12, and a final lens LL, which are disposed in this order from the object side to the image side. The optical system further includes a first diaphragm C1, an aperture stop S, and a second diaphragm C2, in this order from the first positive lens L14 to the image side.

In the optical system according to the present example, the aspheric surface of the first negative lens L11, which has the aspheric surface, has at least one inflection point in a cross-section including the optical axis OA. This configuration can reduce the number of lenses of the optical system while facilitating a wide angle of view of the optical system. Additionally, it is desirable that the object-side surface of the first negative lens L11 be aspheric, and furthermore, it is more desirable that the first negative lens L11 be disposed closest to the object.

The optical system according to the present example includes the aperture stop S between the first positive lens L14 and the cemented lens AT11. This configuration makes it possible to satisfactorily correct aberrations even with a bright F-number. The arrangement of the aperture stop S is not limited to this, and similar advantageous effect can be achieved by arranging the aperture stop S between the third negative lens L13 and the first positive lens L14, or between the first positive lens L14 and the cemented lens AT11.

The optical system according to the present example includes the first diaphragm C1. The first diaphragm C1 can adjust the F-number by blocking the outermost off-axial light beam (light beam that reaches the outermost off-axial image height). Increasing the F-number in the outermost off-axis region of the angle of view prevents or reduces degradation of optical performance due to manufacturing errors. In addition, it is sufficient for the first diaphragm C1 to limit the off-axial light beam (block part of the off-axial light beam).

Moreover, it is desirable that the first diaphragm C1 be disposed adjacent to the aperture stop S. It is more desirable that the first diaphragm C1 be disposed on the object side of the aperture stop S. The first diaphragm C1 is disposed on the object side of the aperture stop S, so that vignetting is induced only in the intermediate to the outermost off-axis region of the angle of view. This enables easy adjustment of the F-number in the intermediate region to the outermost off-axis region of the angle of view.

The optical system according to the present example includes the second diaphragm C2 that is different from the first diaphragm C1.

The second diaphragm C2 is disposed on the image side of the aperture stop S and the first diaphragm C1, and can adjust the F-number by blocking the outermost off-axial light beam (light beam reaching the outermost off-axial image height). It is desirable that the second diaphragm C2 be disposed at a position at which the distance between the second diaphragm C2 and the aperture stop S is smaller than the distance between the first diaphragm C1 and the aperture stop S. This configuration makes it easy to adjust the F-number in the outermost off-axis region. It is sufficient for the second diaphragm C2 to limit the off-axial light beam (block part of the off-axial light beam).

The third negative lens L13 is a meniscus lens whose object-side surface is concave. In other examples, the third negative lens L13 may be a cemented lens, but in that case, the third negative lens L13 is also a meniscus lens whose object-side surface is concave and has an overall negative refractive power. The first positive lens L14 of the optical system according to the present example is located on the object side of the aperture stop S. In other examples, the first positive lens L14 is located on the image side of the aperture stop S, but the same advantageous effect can be achieved in such cases as well.

In the present example, the first cemented lens AT11 and the second cemented lens AT12 are disposed in this order from the object side to the image side, on the image side of the aperture stop S. Disposing a plurality of cemented lenses with positive refractive power on the image side of the aperture stop S has the effect of distributing the positive refractive power and preventing or reducing the occurrence of aberration. The first cemented lens AT11 includes a positive lens L15 and a negative lens L16 cemented on the object side of the positive lens L15. The second cemented lens AT12 includes a positive lens L17 and a negative lens L18 cemented on the object side of the positive lens L17.

The final lens LL is the lens arranged closest to the image plane, and is a positive lens with an aspheric surface in the present example. It is desirable that the final lens LL include an aspheric surface in order to suitably correct field curvature.

In each cemented lens of the present example, an adhesive or the like is applied between the positive lens and the negative lens in this order from the object side, so that they are in close contact with each other. Although the cover glass CG is arranged between the sensor surface IM and the final lens LL, the advantageous effect of the present exemplary embodiment can be obtained even by disposing a spectral filter, such as a wavelength-selective filter. The presence or absence of a filter F and the wavelength range may be changed as appropriate.

In order to control the F-number with high accuracy using the aperture stop S, it is desirable for the optical system to be telecentric on the image side. In each example, telecentricity refers to the absence of angular deviation of the peripheral rays of the light beam with respect to the optical axis of the principal ray of the light beam passing through the optical system. However, achieving high accuracy in F-number control is not limited to cases where the angular deviation of the peripheral rays of the light beam with respect to the optical axis of the principal rays of the light beam passing through the optical system is zero (parallel). Reducing the angular deviation (increasing the degree of telecentricity) can also enhance the accuracy of F-number control. The telecentricity can be increased by arranging an aperture stop at a position close to the object surface, for example.

In the present example, the first negative lens L11 and the second negative lens L12 share the negative refractive power, thus preventing or reducing the occurrence of magnification chromatic aberration. When the focal length of the first negative lens L11 is f1, the focal length of the second negative lens L12 is f2, and the focal length of the entire system is f, it is desirable that at least one of the following inequalities (1) and (2):

$$- 17. 70 < f 1 / f < - 1 \text{.50} , and \qquad ( 1 )$$

$$- 22. 50 < f 2 / f < - 0 \text{.70} . \qquad ( 2 )$$

If f1/f exceeds the upper limit value of the inequality (1), the negative refractive power of the first negative lens L11 becomes too small, making it difficult to effectively correct spherical aberration. Conversely, if f1/f falls below the lower limit value of the inequality (1), the negative refractive power of the first negative lens L11 becomes too large, making various aberrations more likely to occur. If f2/f exceeds the upper limit value of the inequality (2), the negative refractive power of the second negative lens L12 becomes too small, making it difficult to effectively correct spherical aberration. Conversely, if f2/f falls below the lower limit value of the inequality (2), the negative refractive power of the second negative lens L12 becomes too large, making various aberrations more likely to occur.

Further, it is desirable that at least one of the following inequalities (1a) and (2a) be satisfied, and it is more desirable that at least one of the following inequalities (1b) and (2b) be satisfied.

$$- 15. 30 < f 1 / f < - 2.10 \qquad ( 1 a )$$

$$- 19. 50 < f 2 / f < - 1.00 \qquad ( 2 a )$$

$$- 13. 00 < f 1 / f < - 2.80 \qquad ( 1 b )$$

$$- 16. 50 < f 2 / f < - 1.30 \qquad ( 2 b )$$

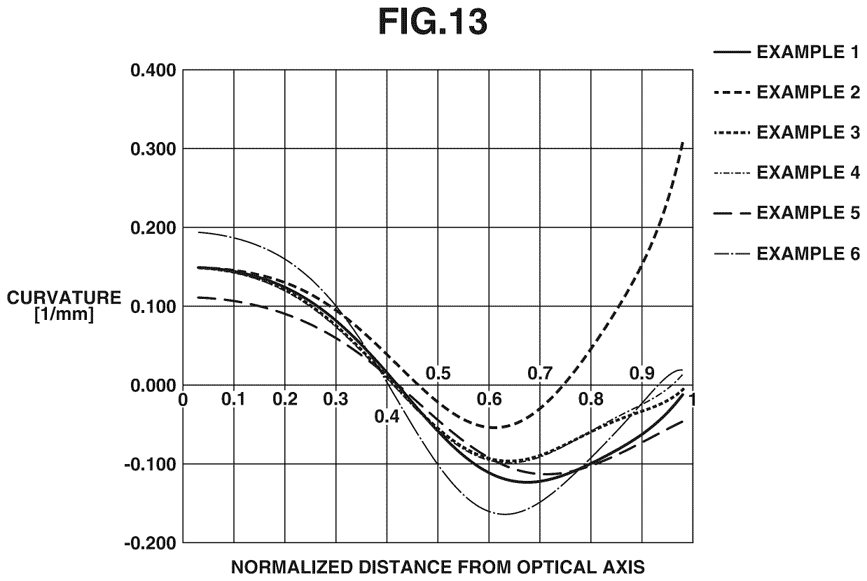

FIG. 13 illustrates the aspherical shape of the first negative lens L11 according to each example. In FIG. 13, the horizontal axis indicates the radial position in the cross-section including the optical axis OA of the aspheric surface of the first negative lens L11, and the vertical axis indicates the curvature [1/mm] of the lens surface of the first negative lens L11. That is, FIG. 13 illustrates a graph plotting the curvature at each position of the aspherical surface of the first negative lens L11. The numerical values on the horizontal axis indicate the distances (normalized distances) from the optical axis OA to the individual positions within the effective diameter of the aspheric surface of the first negative lens L11, in a case where the distance from the optical axis OA to the position of the effective diameter (maximum effective diameter) is normalized to 1.

The aspheric surface of the first negative lens L11 according to each example desirably has at least one inflection point and at least one extremum (minimum value) in the graph representing the curvature versus distance from the optical axis OA illustrated in FIG. 13. As illustrated in FIG. 13, each of the graphs according to the examples has an extremum. This enables the difference in imaging magnification between the central region and the peripheral region of the optical system to be accentuated. Specifically, it enables the imaging magnification of the central region to be greater than that of the peripheral region, thus improving the visibility of the image for the user of the imaging device.

In the aspheric surface of the first negative lens L11 according to each example, when the normalized distance from the optical axis OA to the position corresponding to the extreme value is E, it is desirable for the optical system according to the corresponding example to satisfy the following inequality (3):

$$0.5 \leq E \leq 0.80 . \qquad ( 3 )$$

Inequality (3) defines an appropriate position of the extreme value. Satisfying inequality (3) makes it easy to achieve a wide angle of view of the optical system. If inequality (3) is not satisfied, it is difficult to appropriately set the imaging magnifications in the central region and the peripheral region.

It is further desirable to satisfy the following inequality (3a), and it is yet further desirable to satisfy the following inequality (3b).

$$0.55 \leq E \leq 0.77 \qquad ( 3 a )$$

$$0.6 \leq E \leq 0.75 \qquad ( 3 b )$$

The third negative lens L13 of the optical system according to the present example is a meniscus lens whose object-side surface is concave. The concave object-side surface of the third negative lens L13 allows off-axis light rays to enter the first positive lens L14 at a gentle angle. This configuration enhances the effect of preventing or reducing degradation of the optical performance of the first positive lens L14, which is significantly affected by manufacturing errors, while minimizing the influence on other aberrations. When the focal length of the third negative lens L13 is f3, it is desirable to satisfy the following inequality (4):

$$- 62.00 < f 3 / f < - 3 \text{.00} . \qquad ( 4 )$$

If f3/f exceeds the upper limit value of inequality (4), the negative refractive power of the third negative lens L13 becomes too small, making it difficult to effectively correct spherical aberration. If f3/f falls below the lower limit value of inequality (4), the negative refractive power of the third negative lens L13 becomes too large, making various aberrations more likely to occur.

Further, it is desirable to satisfy the following inequality (4a), and it is more desirable to satisfy inequality (4b).

$$- 57. 50 < f 3 / f < - 3.30 \qquad ( 4 a )$$

$$- 53. 00 < f 3 / f < - 3.50 \qquad ( 4 b )$$

In order to suitably correct spherical aberration and astigmatic aberration, it is desirable that the first positive lens L14 according to the present example have an aspheric surface. In addition, when the focal length of the first positive lens L14 is f4, it is desirable to satisfy the following inequality (5):

$$0.7 < f 4 / f < 3 \text{.40} . \qquad ( 5 )$$

If f4/f exceeds the upper limit value of inequality (5), the refractive power of the first positive lens L14 becomes too large, making various aberrations more likely to occur. If f4/f falls below the lower limit value of inequality (5), the refractive power of the first positive lens L14 becomes too small, making it difficult to suitably correct spherical aberration and astigmatic aberration.

It is further desirable to satisfy the following inequality (5a). It is yet further desirable to satisfy inequality (5b).

$$1. < f 4 / f < 2 \text{.90} \qquad ( 5 a )$$

$$1.3 < f 4 / f < 2 \text{.50} \qquad ( 5 b )$$

In the optical system according to the present example, the cemented lenses with positive refractive power are disposed on the image side of the aperture stop S. The cemented lenses arranged on the image side of the aperture stop S can correct chromatic aberration at locations where the height of the on-axial light beam is high.

Here, let the Abbe numbers of the positive lens and the negative lens in each of the cemented lens on the image side of the aperture stop S, based on the d-line (wavelength 587.56 nm), be denoted as vA and vB, respectively. Further, when the focal lengths of the positive lens and the negative lens in each cemented lens on the image side of the aperture stop S are denoted as fA and fB, it is desirable to satisfy the following inequalities (6) and (7).

$$0.3 < \vert fB / fA \vert < 3.2 \qquad ( 6 )$$

$$0.2 < ν B / ν A < 0. 80 \qquad ( 7 )$$

If inequalities (6) and (7) are not satisfied, the balance of the dispersion ratios will be disrupted, making it difficult to prevent or reduce the occurrence of chromatic aberration and field curvature.

It is further desirable to satisfy the following inequalities (6a) and (7a), and it is yet further desirable to satisfy the following inequalities (6b) and (7b).

$$0.4 < \vert fB / fA \vert < 2.8 \qquad ( 6 a )$$

$$0.3 < vB / vA < 0. 70 \qquad ( 7 a )$$

$$0.5 < \vert 1 B / fA \vert < 2.4 \qquad ( 6 b )$$

$$0.4 < ν B / ν A < 0.6 \qquad ( 7 b )$$

In the present example, a plurality of cemented lenses is arranged on the image side of the aperture stop S. When at least one of the cemented lenses arranged on the image side of the aperture stop S satisfies inequalities (6) and (7), the occurrence of chromatic aberration and field curvature can be prevented or reduced. When all the plurality of cemented lenses arranged on the image side of the aperture stop S satisfies inequalities (6) and (7), the effect of preventing or reducing the occurrence of chromatic aberration and field curvature can be further enhanced.

In the present example, the final lens LL is a positive lens having an aspheric surface. When the focal length of the final lens LL is denoted as f9, it is more suitable for correcting field curvature by satisfying the following inequality (8):

$$1.9 < \vert f 9 / f \vert < 184.4 \qquad ( 8 )$$

If the upper limit value of inequality (8) is exceeded, the absolute value of the refractive power of the final lens LL becomes too large, making various aberrations more likely to occur. If the lower limit value of inequality (8) is not met, the absolute value of the refractive power of the final lens LL becomes too small, making it difficult to suitably correct the field curvature.

It is further desirable to satisfy the following inequality (8a), and it is yet further desirable to satisfy the following inequality (8b):

$$2.7 < \vert f 9 / f \vert < 159.9 \qquad ( 8 a )$$

$$3.4 < \vert f 9 / f \vert < 135.3 \qquad ( 8 b )$$

Satisfying inequalities as described above can reduce the influence of manufacturing errors while providing a lens with a wide angle of view and high resolution at the center of the angle of view.

FIG. 2 is a diagram illustrating the MTF curves of the optical system according to the present example. In the present example, it is assumed that an imaging element with a pixel pitch of 2.1 μm is arranged on the image plane IM. As illustrated in FIG. 2, the minimum MTF value at a spatial frequency of 120 cycles/mm, which is equivalent to half the Nyquist frequency, is approximately 65%, so that excellent imaging performance is achieved.

### Example 2

Hereinafter, an optical system according to Example 2 will be described. In the optical system according to the present example, the descriptions of components equivalent to those of the optical system according to Example 1 described above will be omitted.

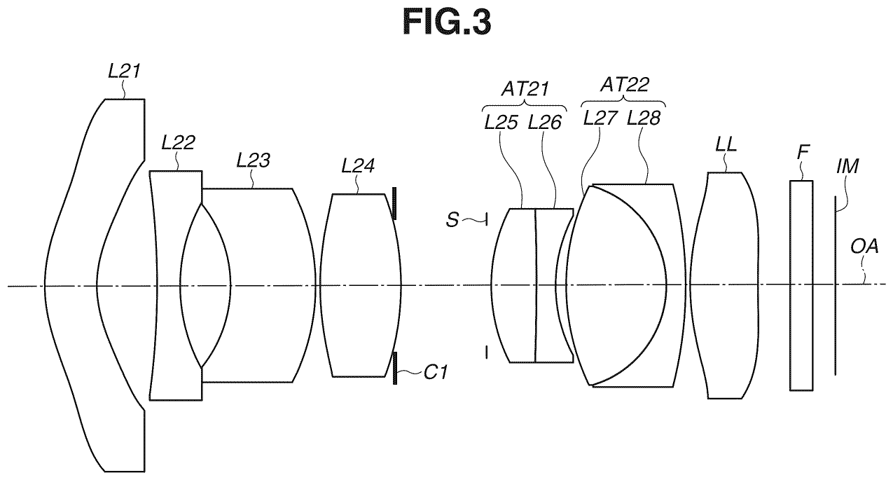

FIG. 3 is a schematic diagram of a main part of the optical system according to Example 2 in a cross-section including an optical axis. The optical system according to the present example differs from the optical system according to Example 1 in the shape and arrangement of lenses.

The optical system according to the present example consists of a first negative lens L21 having an aspheric surface, a second negative lens L22, a third negative lens L23, a first positive lens L24, a first cemented lens AT21, a second cemented lens AT22, and a final lens LL, which are arranged in this order from the object side to the image side. The optical system further includes a first diaphragm C1 and an aperture stop S, in this order from the first positive lens L24 to the image side.

In the present example, the first cemented lens AT21 and the second cemented lens AT22 are arranged, in this order from the object side to the image side, on the image side of the aperture stop S. The first cemented lens AT21 includes a positive lens L25 and a negative lens L26 cemented to the object side of the positive lens L25. The second cemented lens AT22 includes a positive lens L27 and a negative lens L28 cemented to the object side of the positive lens L27.

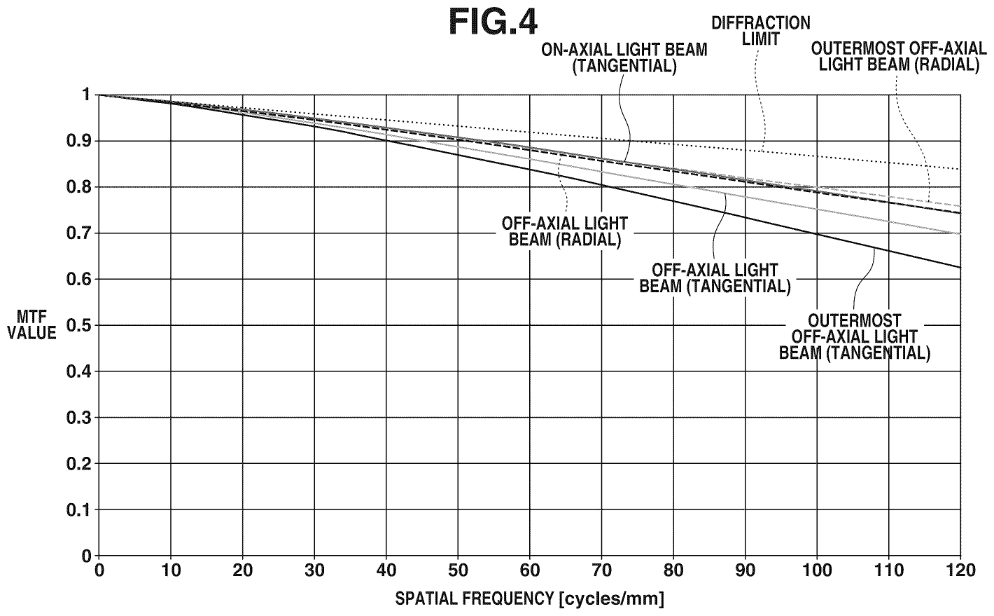

FIG. 4 is a diagram illustrating MTF curves of the optical system according to the present example. In the present example, it is assumed that an imaging element with a pixel pitch of 2.1 μm is arranged on the image plane IM. As illustrated in FIG. 4, the minimum MTF value at a spatial frequency of 120 cycles/mm, which is equivalent to half the Nyquist frequency, is approximately 63%, so that excellent imaging performance is achieved.

### Example 3

Hereinafter, an optical system according to Example 3 will be described. In the optical system according to the present example, the descriptions of the components equivalent to those of the optical system according to Example 1 described above will be omitted.

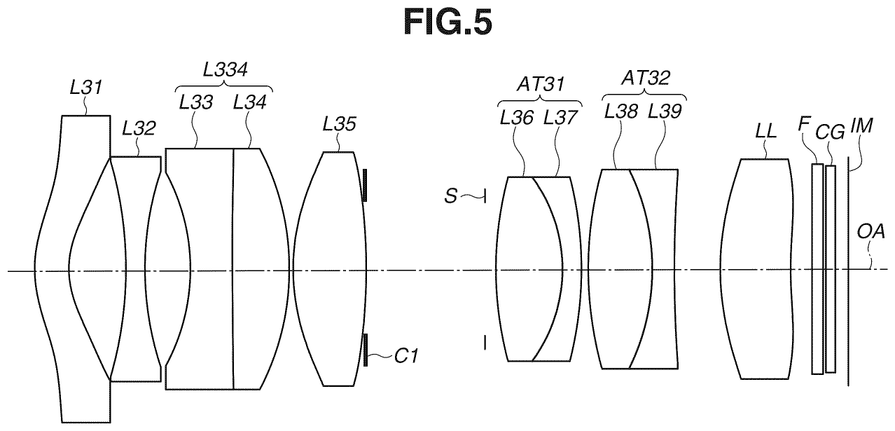

FIG. 5 is a schematic diagram of a main part of the optical system according to Example 3 in a cross-section including an optical axis. The optical system according to the present example differs from the optical system according to Example 1 in the shape and arrangement of lenses.

The optical system according to the present example consists of a first negative lens L31 having an aspheric surface, a second negative lens L32, a third negative lens L334, a first positive lens L35, a first cemented lens AT31, a second cemented lens AT32, and a final lens LL, which are arranged in this order from the object side to the image side. The optical system further includes a first diaphragm C1 and an aperture stop S, in this order from the first positive lens L35 to the image side.

The third negative lens L334 is a cemented lens including a negative lens L33 and a positive lens L34 cemented to the object side of the negative lens L33. The third negative lens L334 is a meniscus lens whose object-side surface is concave, and is equivalent to the third negative lens L13 in Example 1.

The first positive lens L35 is equivalent to the first positive lens L14 in Example 1.

In the present example, the first cemented lens AT31 and the second cemented lens AT32 are arranged, in this order from the object side to the image side, on the image side of the aperture stop S. The first cemented lens AT31 includes a positive lens L36 and a negative lens L37 cemented to the object side of the positive lens L36. The second cemented lens AT32 includes a positive lens L38 and a negative lens L39 cemented to the object side of the positive lens L39.

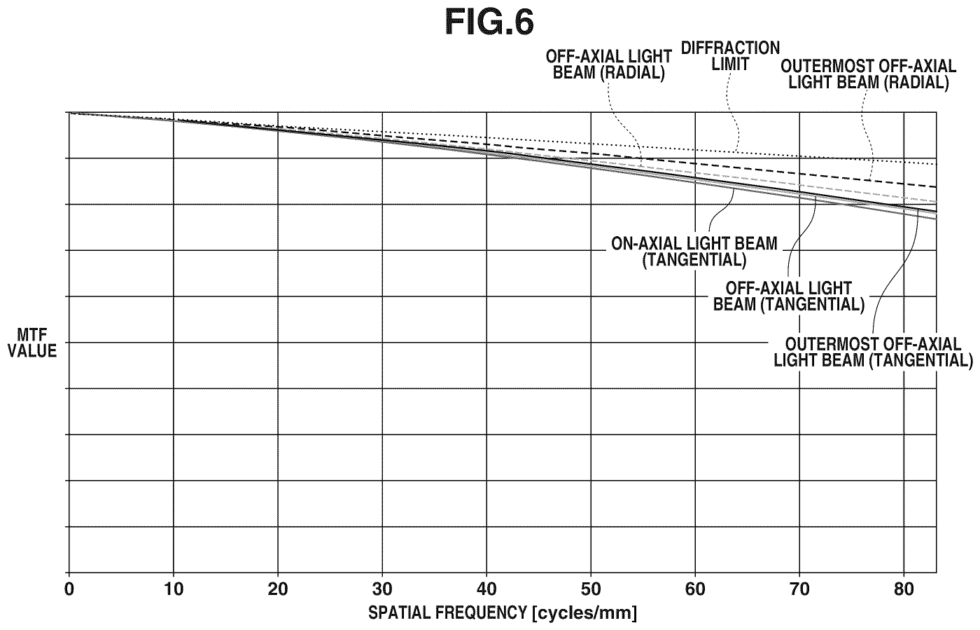

FIG. 6 is a diagram illustrating MTF curves of the optical system according to the present example. In the present example, it is assumed that an imaging element with a pixel pitch of 3.0 μm is arranged on the image plane IM. As illustrated in FIG. 6, the minimum MTF value at a spatial frequency of 83 cycles/mm, which is equivalent to half the Nyquist frequency, is approximately 78%, so that excellent imaging performance is achieved.

### Example 4

Hereinafter, an optical system according to Example 4 will be described. In the optical system according to the present example, the descriptions of the components equivalent to those of the optical system according to Example 1 described above will be omitted.

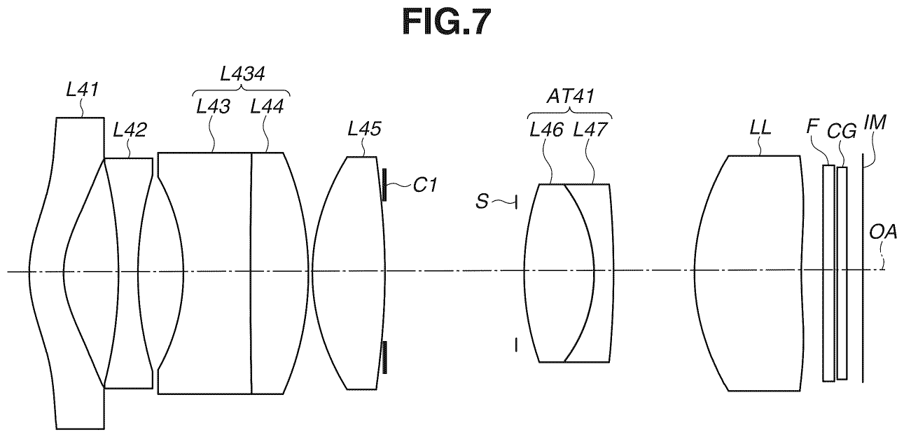

FIG. 7 is a schematic diagram of a main part of the optical system according to Example 4 in a cross-section including an optical axis. The optical system according to the present example differs from the optical system according to Example 1 in the shape and arrangement of lenses.

The optical system according to the present example consists of a first negative lens L41 having an aspheric surface, a second negative lens L42, a third negative lens L434, a first positive lens L45, a first cemented lens AT41, and a final lens LL, which are arranged in this order from the object side to the image side. The optical system further includes a first diaphragm C1 and an aperture stop S, in this order from the first positive lens L45 to the image side.

The third negative lens L434 is a cemented lens including a negative lens L43 and a positive lens L44 cemented to the object side of the negative lens L43. The third negative lens L434 is a meniscus lens whose object-side surface is concave, and is equivalent to the third negative lens L13 in Example 1. The first positive lens L45 is equivalent to the first positive lens L14 in Example 1.

In the present example, a first cemented lens AT41 is arranged on the image side of the aperture stop S. The first cemented lens AT41 includes a positive lens L46 and a negative lens L47 cemented to the object side of the positive lens L46.

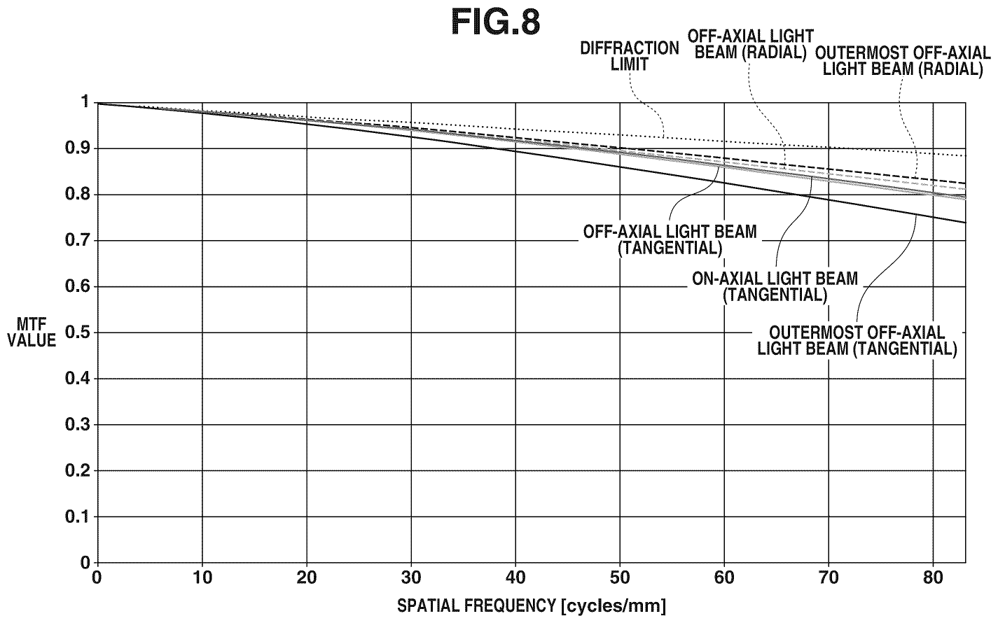

FIG. 8 is a diagram illustrating MTF curves of the optical system according to the present example. In the present example, it is assumed that an imaging element with a pixel pitch of 3.0 μm is arranged in the image plane IM. As illustrated in FIG. 8, the minimum MTF value at a spatial frequency of 83 cycles/mm, which is equivalent to half the Nyquist frequency, is approximately 74%, so that excellent imaging performance is achieved.

### Example 5

Hereinafter, an optical system according to Example 5 will be described. In the optical system according to the present example, the descriptions of the components equivalent to those of the optical system according to Example 1 described above will be omitted.

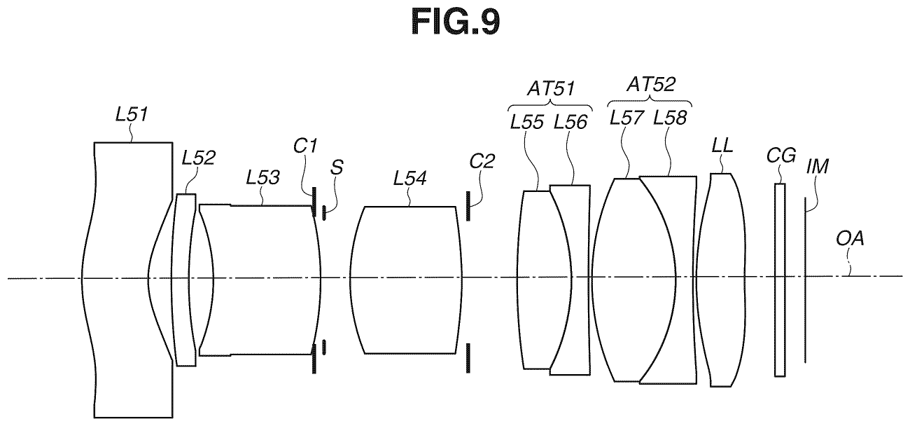

FIG. 9 is a schematic diagram of a main part of the optical system according to Example 5 in a cross-section including an optical axis. The optical system according to the present example differs from the optical system according to Example 1 in the shape and arrangement of lenses.

The optical system according to the present example consists of a first negative lens L51 having an aspheric surface, a second negative lens L52, a third negative lens L53, a first positive lens L54, a first cemented lens AT51, a second cemented lens AT52, and a final lens LL, which are arranged in this order from the object side to the image side. The optical system further includes a first diaphragm C1, an aperture stop S, the first positive lens L54, and a second diaphragm C2, in this order from the third negative lens L53 to the image side.

In the present example, the first cemented lens AT51 and the second cemented lens AT52 are arranged, in this order from the object side to the image side, on the image side of the aperture stop S. The first cemented lens AT51 includes a positive lens L55 and a negative lens L56 cemented to the object side of the positive lens L55. The second cemented lens AT52 includes a positive lens L57 and a negative lens L58 cemented to the object side of the positive lens L57.

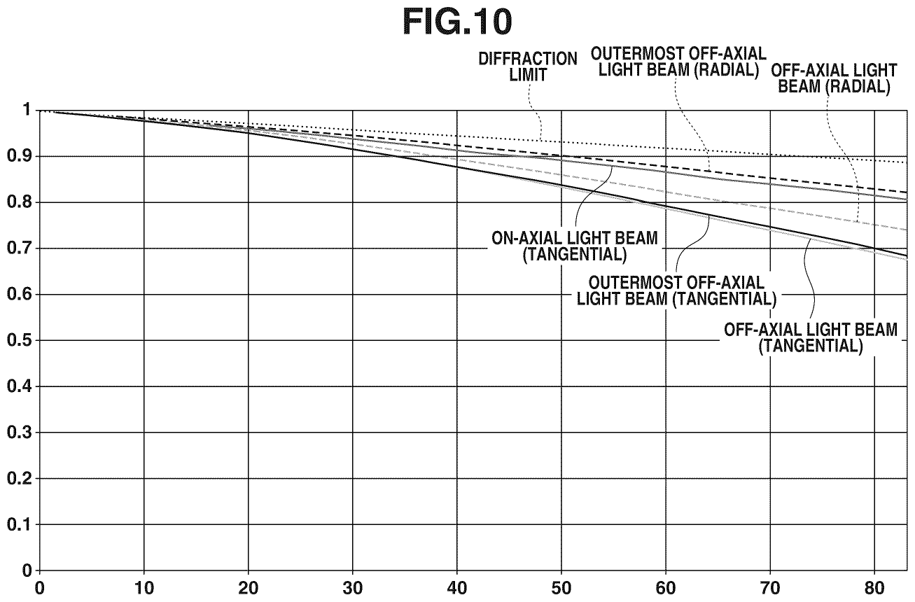

FIG. 10 is a diagram illustrating MTF curves of the optical system according to the present example. In the present example, it is assumed that an imaging element with a pixel pitch of 3.0 μm is arranged in the image plane IM. As illustrated in FIG. 10, the minimum MTF value at a spatial frequency of 83 cycles/mm, which is equivalent to half the Nyquist frequency, is approximately 68%, so that excellent imaging performance is achieved.

### Example 6

Hereinafter, an optical system according to Example 6 will be described. In the optical system according to the present example, the descriptions of the components equivalent to those of the optical system according to Example 1 described above will be omitted.

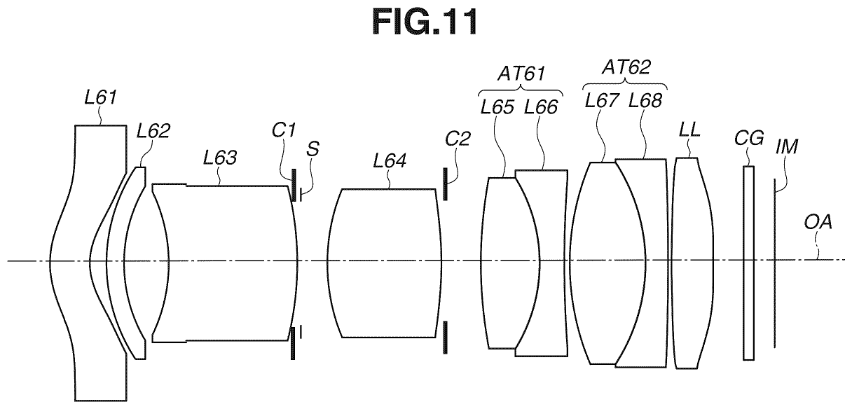

FIG. 11 is a schematic diagram of a main part of the optical system according to Example 6 in a cross-section including an optical axis. The optical system according to the present example differs from the optical system according to Example 1 in the shape and arrangement of lenses.

The optical system according to the present example consists of a first negative lens L61 having an aspheric surface, a second negative lens L62, a third negative lens L63, a first positive lens L64, a first cemented lens AT61, a second cemented lens AT62, and a final lens LL, which are arranged in this order from the object side to the image side. The optical system further includes a first diaphragm C1, an aperture stop S, and a second diaphragm C2, in this order from the third negative lens L63 to the image side.

In the present example, the first cemented lens AT61 and the second cemented lens AT62 are arranged, in this order from the object side to the image side, on the image side of the aperture stop S. The first cemented lens AT61 includes a positive lens L65 and a negative lens L66 cemented to the object side of the positive lens L65. The second cemented lens AT62 includes a positive lens L67 and a negative lens L68 cemented to the object side of the positive lens L67.

The final lens LL in the present example is a negative lens having an aspheric surface.

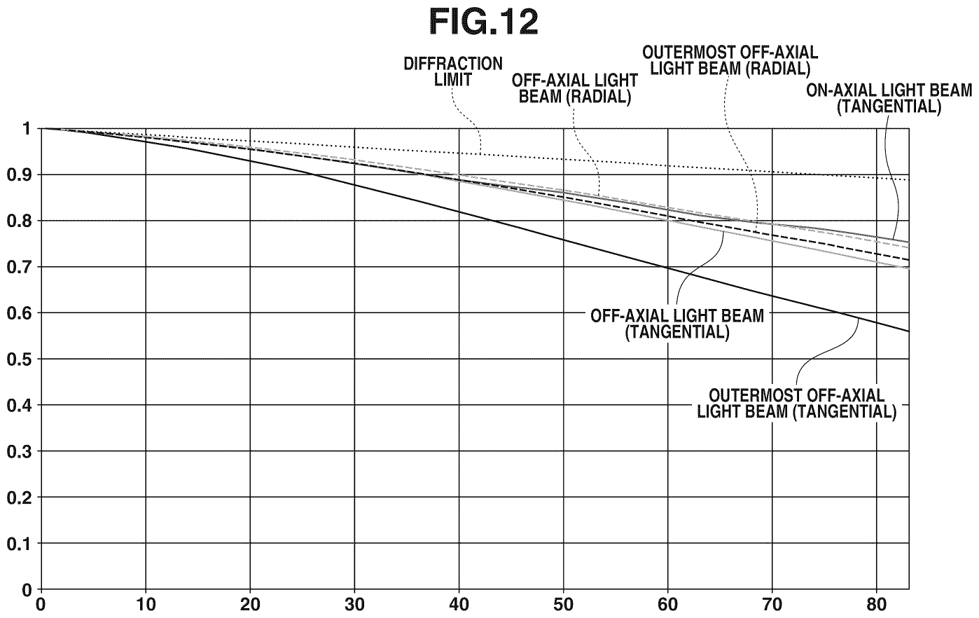

FIG. 12 is a diagram illustrating MTF curves of the optical system according to the present example. In the present example, it is assumed that an imaging element with a pixel pitch of 3.0 μm is arranged in the image plane IM. As illustrated in FIG. 12, the minimum MTF value at a spatial frequency of 83 cycles/mm, which is equivalent to half the Nyquist frequency, is approximately 56%, so that excellent imaging performance is achieved.

In the case of using the optical system of each example in an imaging device, an imaging element is arranged in addition to the optical system. The imaging element is a charge coupled device (CCD) sensor, a complementary metal-oxide semiconductor (CMOS) sensor, or the like.

As the imaging element, an imaging element with a plurality of light receiving units in one pixel may be used. Specifically, each of the plurality of pixels in the imaging element may have a first light receiving unit and a second light receiving unit for receiving an optical image formed through the optical system according to any of the examples. Thus, light incident on one pixel in the imaging element is received by the first light receiving unit or the second light receiving unit depending on the incident angle, for example. That is, the first light receiving unit and the second light receiving unit receive light incident at different incident angles. The incident angle of light is determined by which part of the pupil in the optical system the light has passed through, in each example. For this reason, the pupil of the optical system is divided into two partial pupils by the two light receiving units, and the two light receiving units in one pixel acquire information obtained by observing the object space from different viewpoints (positions within the pupil).

The above-described imaging element, the optical system in any of the examples, and processing unit described below can constitute a distance measuring device such as an in-vehicle camera.

### Numerical Examples

Hereinafter, Numerical Examples 1 to 6 corresponding to above-described Examples 1 to 6 will be provided. In each numerical example, the surface number is the order of each optical surface when counted from the object surface. In each numerical example, r [mm] indicates the radius of curvature of the i-th optical surface, and d [mm] indicates the distance (along the optical axis) between the i-th optical surface and an (i+1)-th optical surface. Additionally, Fno indicates the aperture value, and the unit of focal length is mm. However, the surface distance d is positive in a direction toward the image surface along the optical path, and is negative in a direction toward the object side.

In each numerical example, nd indicates the refractive index of a medium between the i-th surface and the (i+1)-th surface with respect to the d-line, and vd indicates the Abbe number of the medium with respect to the d-line. The Abbe number vd is a value defined by the following formula where the refractive indices for the F-line, d-line, and C-line are nF, nd, and nC, respectively:

$$ν d = ( nd - 1 ) / ( n F - nC )$$

In each numerical example, optical surfaces with an asterisk (*) next to the surface number are aspheric. Also, “E±X” means “10^{±X}”. The aspheric optical surface(s) in each numerical example is/are rotationally symmetric about the optical axis A, and is expressed by the following aspherical equation.

The sag amount Z [mm] in the optical direction indicating the shape of each aspheric surface is expressed by the following equation.

$$Z = \frac{( 1 / r ) {h}^{2}}{1 + \sqrt{1 - ( 1 + k ) {( 1 / r )}^{2} {h}^{2}}} + A {h}^{4} + B {h}^{6} + C {h}^{8} + D {h}^{10} + E {h}^{12} + F {h}^{14}$$

In the above aspherical equation, k is the conic constant, h is the distance [mm] in the radial direction from the optical axis, and A to F are aspherical coefficients for the 4th to 14th order terms. The terms from the second term onward represent the sag amount (aspherical amount) of the aspherical component added to the reference spherical surface.

Although only aspherical coefficients of the 4th to 14th order terms are used here, aspherical coefficients for terms of 16th order or higher may be used if necessary. In each numerical example, in a case where the optical surface is aspherical, the radius of curvature of the reference spherical surface is used as the radius of curvature of the optical system, and this radius of curvature satisfies an inequality or inequalities as described above.

The glass material in each example is optical glass from OHARA Inc., HOYA Corporation, or the like. However, equivalent products from other manufacturers may also be used.

(Numerical Example 1)
Various types of data

| | |
|---|---|
| Center focal length | 5.8 mm |
| Fno | 1.8 |
| Half angle of view | ±60° |
| Designed wavelength | 486.1 to 656.27 nm |

Surface Data

| | Surface | | | Glass |
|---|---|---|---|---|
| | number | r | d | material |
| Object | 0 | ∞ | ∞ | |
| surface | | | | |
| L11 | 1* | 6.70 | 3.36 | MBACD12_HOYA |
| | 2* | 3.32 | 2.51 | |
| L12 | 3 | 58.57 | 1.00 | SBAL35_OHARA |
| | 4 | 12.04 | 2.55 | |
| L13 | 5 | −7.19 | 5.90 | STIH4_OHARA |
| | 6 | −12.07 | 0.20 | |
| L14 | 7* | 8.78 | 7.98 | MBACD12_HOYA |
| | 8* | −37.04 | 2.05 | |
| S (stop) | 9 | ∞ | 0.43 | |
| L15 | 10 | 12.26 | 2.47 | SPHM53_OHARA |
| L16 | 11 | −11.71 | 0.85 | STIM28_OHARA |
| | 12 | 11.67 | 0.37 | |
| L17 | 13 | 14.41 | 4.93 | SFPM2_OHARA |
| L18 | 14 | −5.63 | 1.56 | SNBH8_OHARA |
| | 15 | −12.35 | 0.20 | |
| LL | 16* | 14.44 | 2.58 | MBACD12_HOYA |
| | 17* | 53.46 | 2.07 | |
| CG | 18 | ∞ | 1.00 | NBK7_SCHOTT |
| | 19 | ∞ | 1.00 | |
| Image | 20 | ∞ | — | |
| plane | | | | |

Aspheric coefficients

| | Surface | Surface | Surface | Surface | Surface | Surface |
|---|---|---|---|---|---|---|
| | number 1 | number 2 | number 7 | number 8 | number 16 | number 17 |
| r | 6.701 | 3.318 | 8.777 | −37.039 | 14.440 | 53.462 |
| k | −4.418 | −1.045 | 0.053 | −6.171 | 0.545 | −1.000 |
| A | 6.036E−04 | −1.843E−03 | −6.378E−05 | 3.822E−04 | −3.788E−04 | −1.128E−03 |
| B | −7.726E−05 | −1.069E−04 | −5.364E−07 | 1.332E−06 | 4.737E−06 | 2.786E−05 |
| C | 2.312E−06 | 9.293E−06 | 7.023E−08 | 1.861E−07 | −8.040E−07 | −1.652E−06 |
| D | −3.450E−08 | −3.136E−07 | −1.825E−09 | 1.657E−09 | 2.236E−08 | 3.703E−08 |
| E | 2.654E−10 | 5.592E−09 | 2.479E−11 | −1.087E−15 | −3.317E−10 | 9.268E−11 |
| F | −8.328E−13 | −4.033E−11 | 0.000E+00 | −3.024E−19 | 1.870E−13 | −1.236E−11 |

(Numerical Example 2)

| | |
|---|---|
| Center focal length | 5.8 mm |
| Fno | 1.8 |
| Half angle of view | ±60° |
| Designed wavelength | 486.1 to 656.27 nm |

Surface Data

| | Surface | | | Glass |
|---|---|---|---|---|
| | number | r | d | material |
| Object | 0 | ∞ | ∞ | |
| surface | | | | |
| L21 | 1* | 6.70 | 2.30 | MBACD12_HOYA |
| | 2* | 5.01 | 2.66 | |
| L22 | 3 | −36.14 | 1.02 | SBAL35_OHARA |
| | 4 | 7.60 | 2.23 | |
| L23 | 5 | −5.71 | 3.76 | STIH4_OHARA |
| | 6 | −9.36 | 0.20 | |
| L24 | 7* | 12.72 | 3.58 | MBACD12_HOYA |
| | 8* | −11.83 | 3.78 | |
| S (stop) | 9 | ∞ | 0.20 | |
| L25 | 10 | 7.43 | 2.00 | SPHM53_OHARA |
| L26 | 11 | −97.10 | 0.85 | STIM28_OHARA |
| | 12 | 6.55 | 0.46 | |
| L27 | 13 | 10.04 | 4.43 | SFPM2_OHARA |
| L28 | 14 | −4.58 | 0.85 | SNBH8_OHARA |
| | 15 | −17.93 | 0.20 | |
| LL | 16* | 10.33 | 3.00 | MBACD12_HOYA |
| | 17* | 35.73 | 1.42 | |
| CG | 18 | ∞ | 1.00 | NBK7_SCHOTT |
| | 19 | ∞ | 1.00 | |
| Image | 20 | ∞ | — | |
| plane | | | | |

Aspheric coefficients

| | Surface | Surface | Surface | Surface | Surface | Surface |
|---|---|---|---|---|---|---|
| | number 1 | number 2 | number 7 | number 8 | number 16 | number 17 |
| r | 6.700 | 5.012 | 12.724 | −11.830 | 10.330 | 35.726 |
| k | −4.045 | −2.819 | −9.513 | −6.206 | 0.545 | −1.000 |
| A | 7.542E−04 | 7.336E−04 | 3.130E−04 | −4.073E−04 | −6.521E−04 | −2.597E−03 |
| B | −7.792E−05 | −1.672E−04 | −1.217E−05 | 2.575E−06 | 1.966E−05 | 7.529E−05 |
| C | 2.293E−06 | 1.052E−05 | −4.382E−07 | −3.182E−07 | −2.633E−06 | −2.300E−06 |
| D | −3.082E−08 | −3.523E−07 | 3.395E−08 | 8.234E−10 | 1.686E−07 | 5.869E−08 |
| E | 1.923E−10 | 7.126E−09 | −1.306E−09 | 4.246E−11 | −7.530E−09 | −2.543E−09 |
| F | −3.770E−1 | −6.318E−11 | 0.000E+00 | −1.039E−11 | 1.255E−10 | 5.005E−11 |

(Numerical Example 3)

| | |
|---|---|
| Center focal length | 7.2 mm |
| Fno | 1.8 |
| Half angle of view | ±60° |
| Designed wavelength | 486.1 to 656.27 nm |

Surface Data

| | Surface | | | Glass |
|---|---|---|---|---|
| | number | r | d | material |
| Object | 0 | ∞ | ∞ | |
| surface | | | | |
| L31 | 1* | 6.700 | 1.80 | MBACD12_HOYA |
| | 2* | 4.66 | 3.00 | |
| L32 | 3 | −20.24 | 1.00 | SLAH55VS_OHARA |
| | 4 | 16.18 | 2.39 | |
| L33 | 5 | −10.65 | 2.21 | SLAH60V_OHARA |
| L34 | 6 | 300.00 | 3.00 | SLAH60MQ_OHARA |
| | 7 | −13.62 | 0.20 | |
| L35 | 8* | 11.07 | 3.85 | MBACD12_HOYA |
| | 9* | −30.06 | 6.25 | |
| S (stop) | 10 | ∞ | 0.57 | |
| L36 | 11 | 18.58 | 3.50 | SPHM53_OHARA |
| L37 | 12 | −8.11 | 1.00 | SLAH95_OHARA |
| | 13 | −19.45 | 0.36 | |
| L38 | 14 | 19.29 | 3.37 | SFPM2_OHARA |
| L39 | 15 | −11.77 | 1.16 | SNBH55_OHARA |
| | 16 | 71.66 | 2.41 | |
| LL | 17* | 13.70 | 3.71 | MBACD12_HOYA |
| | 18* | 20.13 | 1.13 | |
| F | 19 | ∞ | 0.58 | NBK7_SCHOTT |
| | 20 | ∞ | 0.15 | |
| CG | 21 | ∞ | 0.50 | NBK7_SCHOTT |
| | 22 | ∞ | 0.81 | |
| Image | 23 | ∞ | — | |
| plane | | | | |

Aspheric coefficients

| | Surface | Surface | Surface | Surface | Surface | Surface |
|---|---|---|---|---|---|---|
| | number 1 | number 2 | number 8 | number 9 | number 17 | number 18 |
| r | 6.700 | 4.660 | 11.070 | −30.058 | 13.702 | 20.128 |
| k | −2.604 | −0.454 | −0.050 | 4.904 | −0.907 | 4.867 |
| A | −2.034E−04 | −1.935E−03 | −1.055E−04 | 7.236E−05 | −1.334E−04 | −1.518E−03 |
| B | −5.669E−05 | −1.115E−04 | −9.949E−07 | −9.140E−07 | 1.837E−06 | 1.907E−05 |
| C | 2.189E−06 | 7.851E−06 | 1.012E−08 | 1.415E−08 | −2.674E−08 | −1.623E−08 |
| D | −3.642E−08 | −2.871E−07 | −1.734E−10 | −1.211E−09 | −2.478E−10 | −2.424E−09 |
| E | 2.938E−10 | 5.956E−09 | −2.211E−11 | 0.000E+00 | 0.000E+00 | 0.000E+00 |
| F | −9.253E−13 | −6.019E−11 | 0.000E+00 | 0.000E+00 | 0.000E+00 | 0.000E+00 |

(Numerical Example 4)

| | |
|---|---|
| Center focal length | 7.2 mm |
| Fno | 1.8 |
| Half angle of view | ±60° |
| Designed wavelength | 486.1 to 656.27 nm |

Surface Data

| | Surface | | | Glass |
|---|---|---|---|---|
| | number | r | d | material |
| Object | 0 | ∞ | ∞ | |
| surface | | | | |
| L41 | 1* | 6.700 | 1.77 | MBACD12_HOYA |
| | 2* | 4.69 | 2.84 | |
| L42 | 3 | −22.68 | 1.00 | SLAH64_OHARA |
| | 4 | 17.14 | 2.35 | |
| L43 | 5 | −10.10 | 3.45 | SLAH60V_OHARA |
| L44 | 6 | 300.00 | 3.00 | SLAH60MQ_OHARA |
| | 7 | −15.32 | 0.20 | |
| L45 | 8* | 10.20 | 3.75 | MBACD12_HOYA |
| | 9* | −33.09 | 6.78 | |
| S (stop) | 10 | ∞ | 0.40 | |
| L46 | 11 | 13.77 | 3.61 | SPHM53_OHARA |
| L47 | 12 | −7.51 | 1.00 | SNBH56_OHARA |
| | 13 | −48.06 | 4.17 | |
| L48 | 14* | 10.51 | 5.52 | MBACD12_HOYA |
| | 15* | 24.14 | 1.12 | |
| F | 16 | ∞ | 0.58 | NBK7_SCHOTT |
| | 17 | ∞ | 0.15 | |
| CG | 18 | ∞ | 0.50 | NBK7_SCHOTT |
| | 19 | ∞ | 0.81 | |
| Image | 20 | ∞ | — | |
| plane | | | | |

Aspheric coefficients

| | Surface | Surface | Surface | Surface | Surface | Surface |
|---|---|---|---|---|---|---|
| | number 1 | number 2 | number 8 | number 9 | number 14 | number 15 |
| r | 6.704 | 4.690 | 10.203 | −33.086 | 10.507 | 24.136 |
| k | −2.879 | −0.450 | −0.594 | 7.112 | −0.484 | 9.628 |
| A | −1.532E−04 | −2.041E−03 | −2.974E−05 | 1.082E−04 | −7.481E−05 | −1.202E−03 |
| B | −5.706E−05 | −1.045E−04 | −1.251E−07 | −1.912E−07 | 8.303E−07 | 1.133E−05 |
| C | 2.162E−06 | 7.577E−06 | 2.425E−08 | 1.552E−08 | −1.615E−08 | 8.386E−08 |
| D | −3.559E−08 | −2.834E−07 | −4.268E−10 | −4.495E−10 | 3.365E−10 | 2.026E−09 |
| E | 2.852E−10 | 5.947E−09 | −1.396E−12 | 0.000E+00 | 0.000E+00 | 0.000E+00 |
| F | −8.920E−13 | −5.976E−11 | 0.000E+00 | 0.000E+00 | 0.000E+00 | 0.000E+00 |

(Numerical Example 5)
Various types of data

| | |
|---|---|
| Center focal length | 9.0 mm |
| Fno | 1.8 |
| Half angle of view | ±60° |
| Designed wavelength | 486.1 to 656.27 nm |

Surface Data

| | Surface | | | Glass |
|---|---|---|---|---|
| | number | r | d | material |
| Object | 0 | ∞ | ∞ | |
| surface | | | | |
| L51 | 1* | 9.00 | 3.85 | MBACD12_HOYA |
| | 2* | 4.99 | 1.35 | |
| L52 | 3 | 39.05 | 1.01 | STIH53W_OHARA |
| | 4 | 21.44 | 1.43 | |
| L53 | 5 | −10.26 | 6.24 | SLAH60V_OHARA |
| | 6 | −17.03 | 0.20 | |
| S (stop) | 7 | ∞ | 1.51 | |
| L54 | 8* | 10.61 | 6.50 | MBACD12_HOYA |
| | 9* | −21.34 | 3.22 | |
| L55 | 10 | 34.37 | 3.16 | SPHM53_OHARA |
| L56 | 11 | −11.27 | 1.00 | STIM35_OHARA |
| | 12 | 152.50 | 0.20 | |
| L57 | 13 | 13.78 | 4.87 | SPHM52_OHARA |
| L58 | 14 | −9.27 | 1.00 | STIH18_OHARA |
| | 15 | 72.37 | 0.20 | |
| LL | 16* | 15.89 | 2.80 | MBACD12_HOYA |
| | 17* | 19.79 | 1.54 | |
| CG | 18 | ∞ | 1.00 | NBK7_SCHOTT |
| | 19 | ∞ | 1.00 | |
| Image | 20 | ∞ | — | |
| plane | | | | |

Aspheric coefficients

| | Surface | Surface | Surface | Surface | Surface | Surface |
|---|---|---|---|---|---|---|
| | number 1 | number 2 | number 8 | number 9 | number 16 | number 17 |
| r | 9.000 | 4.990 | 10.612 | −21.336 | 15.893 | 19.789 |
| k | −9.034 | −0.831 | −0.490 | −3.026 | −10.000 | 6.923 |
| A | 4.846E−04 | −2.191E−03 | −7.605E−05 | 9.895E−05 | −4.879E−04 | −4.421E−03 |
| B | −6.792E−05 | −3.561E−05 | 1.473E−06 | 3.479E−06 | 6.844E−05 | 2.616E−04 |
| C | 2.122E−06 | 5.236E−06 | 6.085E−08 | −1.059E−07 | −3.803E−06 | −1.158E−05 |
| D | −3.334E−08 | −1.949E−07 | −6.557E−09 | 5.305E−09 | 1.142E−07 | 3.333E−07 |
| E | 2.764E−10 | 3.682E−09 | 3.545E−10 | −2.876E−10 | −1.761E−09 | −5.515E−09 |
| F | −9.671E−13 | −2.637E−11 | −6.105E−12 | 8.913E−12 | 8.837E−12 | 3.719E−11 |

(Numerical Example 6)

| | |
|---|---|
| Center focal length | 5.8 mm |
| Fno | 2.0 |
| Half angle of view | ±60° |
| Designed wavelength | 486.1 to 656.27 nm |

Surface Data

| | Surface | | | Glass |
|---|---|---|---|---|
| | number | r | d | material |
| Object | 0 | ∞ | ∞ | |
| surface | | | | |
| L61 | 1* | 5.14 | 2.27 | MBACD12_HOYA |
| | 2* | 3.49 | 0.95 | |
| L62 | 3 | 9.77 | 1.00 | STIH53W_OHARA |
| | 4 | 8.59 | 2.55 | |
| L63 | 5 | −9.41 | 7.32 | SLAH60V_OHARA |
| | 6 | −17.71 | 0.20 | |
| S (stop) | 7 | ∞ | 1.51 | |
| L64 | 8* | 10.98 | 6.50 | MBACD12_HOYA |
| | 9* | −20.29 | 2.25 | |
| L65 | 10 | 25.91 | 3.35 | SPHM53_OHARA |
| L66 | 11 | −9.24 | 1.41 | STIM35_OHARA |
| | 12 | 64.56 | 0.31 | |
| L67 | 13 | 14.58 | 4.32 | SPHM52_OHARA |
| L68 | 14 | −10.47 | 1.29 | STIH18_OHARA |
| | 15 | −141.90 | 0.20 | |
| LL | 16* | 53.11 | 2.37 | MBACD12_HOYA |
| | 17* | 48.31 | 1.50 | |
| CG | 18 | ∞ | 1.00 | NBK7_SCHOTT |
| | 19 | ∞ | 1.00 | |
| Image | 20 | ∞ | — | |
| plane | | | | |

Aspheric coefficients

| | Surface | Surface | Surface | Surface | Surface | Surface |
|---|---|---|---|---|---|---|
| | number 1 | number 2 | number 8 | number 9 | number 16 | number 17 |
| r | 5.144 | 3.491 | 10.984 | −20.293 | 53.114 | 48.306 |
| k | −4.652 | −0.831 | −0.490 | −3.026 | −10.000 | 6.923 |
| A | 2.089E−03 | −2.912E−03 | −1.213E−05 | 1.507E−04 | −1.202E−03 | −5.433E−03 |
| B | −2.389E−04 | −1.995E−04 | 4.780E−06 | 9.037E−06 | 1.529E−04 | 4.420E−04 |
| C | 8.953E−06 | 1.732E−05 | −3.048E−07 | −8.979E−07 | −1.051E−05 | −2.444E−05 |
| D | −1.729E−07 | −6.170E−07 | 1.937E−08 | 7.250E−08 | 4.123E−07 | 8.505E−07 |
| E | 1.753E−09 | 1.114E−08 | −4.808E−10 | −2.699E−09 | −8.593E−09 | −1.639E−08 |
| F | −7.391E−12 | −7.792E−11 | 2.962E−12 | 3.730E−11 | 7.402E−11 | 1.330E−10 |

The following table presents values related to the inequalities for the optical systems according to the above-described examples. As in the table, the optical systems according to the examples satisfy each inequality.

TABLE 1

| | | Exam- | Exam- | Exam- | Exam- | Exam- | Exam- |
|---|---|---|---|---|---|---|---|
| | | ple | ple | ple | ple | ple | ple |
| | | 1 | 2 | 3 | 4 | 5 | 6 |
| | f | 5.8 | 5.8 | 7.2 | 7.2 | 9.0 | 9.0 |
| | f1 | −17.74 | −68.44 | −38.58 | −39.30 | −29.51 | −37.50 |
| | f2 | −25.88 | −10.54 | −10.47 | −12.07 | −56.03 | −135.00 |
| | f3 | −48.94 | −34.75 | −296.96 | −80.77 | −52.66 | −39.70 |
| | f4 | 12.97 | 11.08 | 14.21 | 13.66 | 14.30 | 13.09 |
| | fA1 | 10.31 | 11.50 | 9.75 | 8.52 | 14.30 | 11.59 |
| | fB1 | −8.32 | −8.83 | −15.71 | −10.24 | −14.63 | −11.21 |
| | fA2 | 7.47 | 5.95 | 12.68 | — | 9.66 | 10.45 |
| | fB2 | −15.82 | −8.75 | −12.27 | — | −11.06 | −15.36 |
| | vA1 | 65.44 | 65.44 | 65.44 | 65.44 | 65.44 | 65.44 |
| | vB1 | 31.07 | 31.07 | 31.30 | 24.80 | 30.13 | 30.13 |
| | vA2 | 67.74 | 67.74 | 67.74 | — | 63.33 | 63.33 |
| | vB2 | 34.71 | 34.71 | 29.84 | — | 29.23 | 29.23 |
| | f9 | 33.03 | 23.82 | 59.92 | 27.42 | 107.99 | −1106.68 |
| (1) | f1/f | −3.06 | −11.80 | −5.36 | −5.46 | −3.28 | −4.17 |
| (2) | f2/f | −4.46 | −1.82 | −1.45 | −1.68 | −6.23 | −15.00 |
| (3) | E | 0.68 | 0.62 | 0.65 | 0.65 | 0.72 | 0.64 |
| (4) | f3/f | −8.44 | −5.99 | −41.24 | −11.22 | −5.85 | −4.41 |
| (5) | f4/f | 2.24 | 1.91 | 1.97 | 1.90 | 1.59 | 1.45 |
| (6) | \|fB1/fA1\| | 0.81 | 0.77 | 1.61 | 1.20 | 1.02 | 0.97 |
| | \|fB2/A2\| | 2.12 | 1.47 | 0.97 | — | 1.15 | 1.47 |
| (7) | vB1/vA1 | 0.47 | 0.47 | 0.48 | 0.38 | 0.46 | 0.46 |
| | vB2/vA2 | 0.51 | 0.51 | 0.44 | — | 0.46 | 0.46 |
| (8) | \|f9/f\| | 5.70 | 4.11 | 8.32 | 3.81 | 12.00 | 122.96 |
| (9) | fx | 1.40 | 1.37 | 1.31 | 1.27 | 1.63 | 1.63 |
| | sin(θmax)/ | | | | | | |
| | y(θmax) | | | | | | |

### Imaging Device

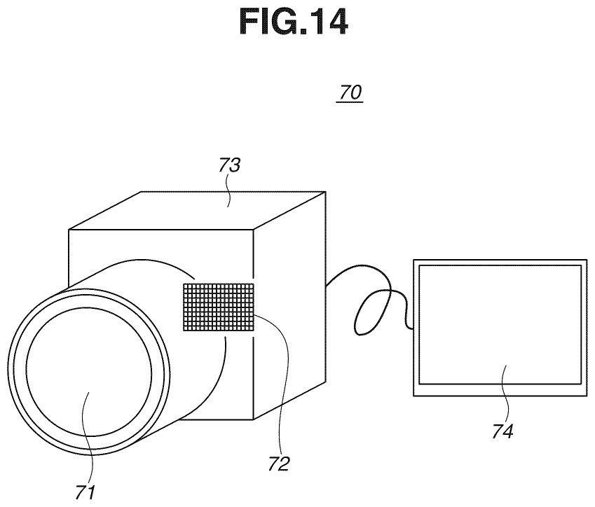

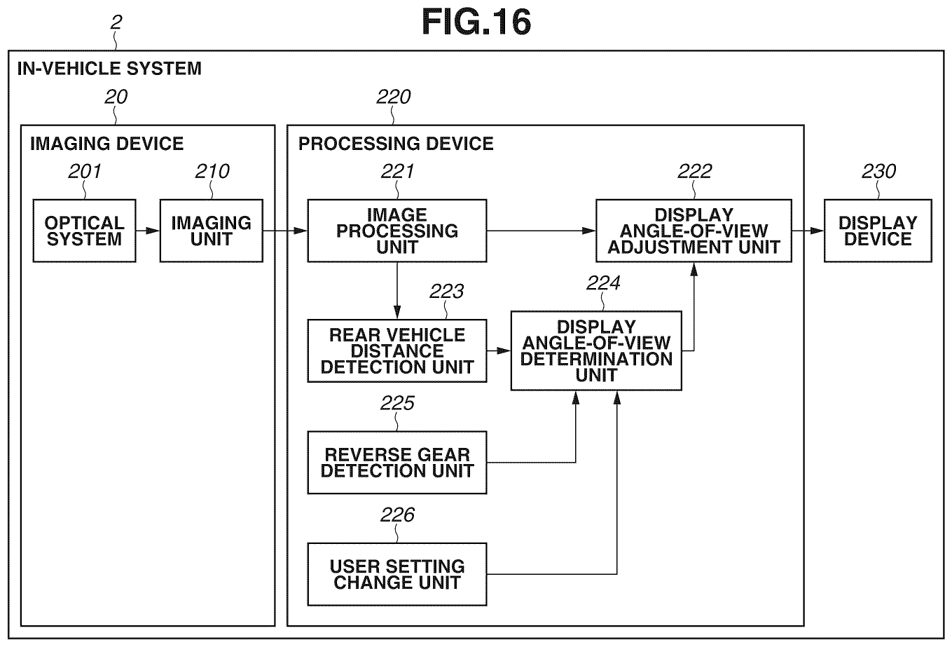

FIG. 14 is a schematic diagram of a main part of an imaging device 70 according to an exemplary embodiment. The imaging device 70 according to the present exemplary embodiment includes an optical system (imaging optical system) 71 according to any one of the above-described examples, a light receiving element 72 that photoelectrically converts an image of an object formed by the optical system 71, and a camera body (housing) 73 that holds the light receiving element 72. The optical system 71 is held by a lens barrel (holding member) and connected to the camera body 73. As illustrated in FIG. 16, the camera body 73 may be connected to a display unit 74 that displays an image acquired by the light receiving element 72. As the light receiving element 72, an imaging element (photoelectric conversion element) such as a CCD sensor or a CMOS sensor can be used.

In the case of using the imaging device 70 as a distance measuring device, for example, an imaging element (imaging surface phase difference sensor) that has pixels capable of splitting the light beam from an object into two and performing photoelectric conversion can be employed as the light receiving element 72. When the object is on the front focal plane of the optical system 71, no positional deviation occurs in each image corresponding to the two split light beams on the image plane of the optical system 71. However, when the object is at a position other than the front focal plane of the optical system 71, positional deviation occurs in each image. At this time, the positional deviation of each image corresponds to the displacement amount from the front focal plane of the object, so that the distance to the object can be measured by obtaining the amount and direction of the positional deviation of each image using the imaging surface phase difference sensor.

The optical system 71 and the camera body 73 may be attachable to and detachable from each other. That is, the optical system 71 and the lens barrel may be an interchangeable lens (lens device). The optical system according to each of the above-described examples is not limited to imaging devices, such as digital still cameras, silver halide film cameras, video cameras, in-vehicle cameras, and surveillance cameras, and can also be applied to various optical devices, such as telescopes, binoculars, projectors (projection devices), and digital copying devices.

### In-Vehicle System

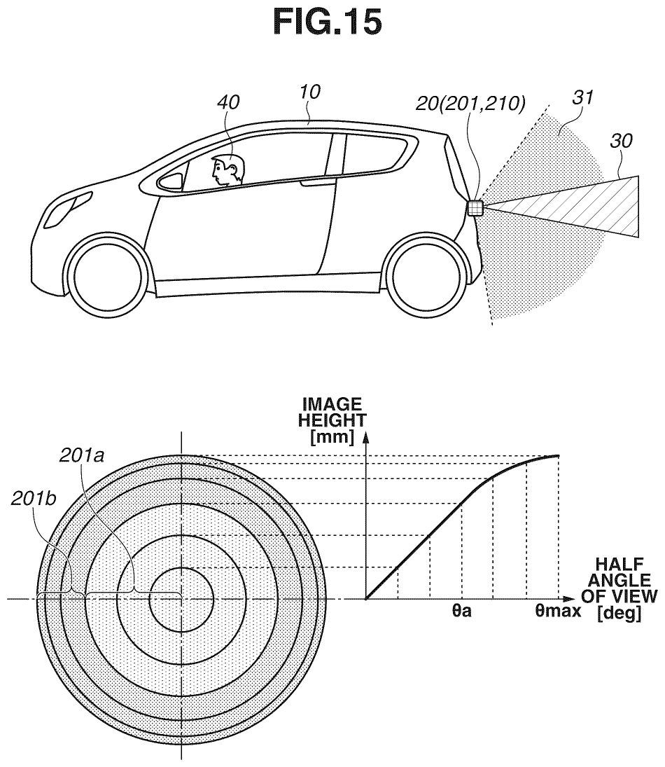

The upper diagram of FIG. 15 is a schematic diagram of a movable apparatus 10 and an imaging device 20 (in-vehicle camera) held by the movable apparatus 10 according to the present exemplary embodiment. In the upper diagram of FIG. 15, the movable apparatus 10 is illustrated as an automobile (vehicle). The movable apparatus 10 includes an in-vehicle system (driving support device, not illustrated) for supporting a user 40 (driver, passenger, or the like) of the movable apparatus 10 using images acquired by the imaging device 20. In the present exemplary embodiment, the imaging device 20 is placed so as to capture an image of the area behind the movable apparatus 10, but the imaging device 20 may be placed so as to capture an image of the area in front or on lateral sides of the movable apparatus 10. In addition, two or more imaging devices 20 may be placed in two or more places on the movable apparatus 10.

The imaging device 20 includes an optical system 201 and an imaging unit 210 according to any one of the above-described examples. The optical system 201 is an optical system (different angle-of-view lens) having different imaging magnifications at a first angle of view (first field of view) 30 and a second angle of view (second field of view) 31 wider than the first angle of view 30. The imaging surface (light receiving surface) of the imaging unit 210 includes a first area for imaging an object included in the first angle of view 30 and a second area for imaging an object included in the second angle of view 31. At this time, the number of pixels per unit angle of view in the first area is greater than the number of pixels per unit angle of view in the second area excluding the first area. In other words, in the imaging device 20, the resolution at the first angle of view (first area) is higher than the resolution at the second angle of view (second area).

The optical characteristics of the optical system 201 will now be described in detail. The lower-left part in FIG. 15 illustrates, in contour lines, an image height y [mm] at each half angle of view θ [deg.] on the imaging surface of the imaging unit 210. The lower-right part in FIG. 15 illustrates, in a graph, the relationship between each half angle of view θ and the image height y (projection characteristic of the optical system 201) in the first quadrant of the left diagram.

As illustrated in the lower part in FIG. 15, the optical system 201 is configured such that the projection characteristic y(θ) differs between an angle of view less than a predetermined half angle of view θa and an angle of view equal to or greater than the half angle of view θa. Thus, the amount of increase in the image height y (resolution) per unit of half angle of view θ also differs at each angle of view. The local resolution of the optical system 201 is expressed as a differential value dy(θ)/dθ of the projection characteristic y(θ) with respect to the half angle of view θ. The lower-left part in FIG. 15 indicates that the larger the interval between the contour lines of the image height y for each half angle of view θ, the higher the resolution. In addition, the lower-right part in FIG. 15 indicates that the larger the slope of the graph of the projection characteristic y(θ), the higher the resolution.

In the lower-left part in FIG. 15, a first area 201a, which is the central area, corresponds to an angle of view less than a half angle of view θa, and a second area 201b, which is the peripheral area, corresponds to an angle of view equal to or greater than the half angle of view θa. The angle of view less than the half angle of view θa corresponds to the first angle of view 30 in the upper diagram of FIG. 15, and the combined angle of view of the angle of view less than the half angle of view θa and the angle of view equal to or greater than the half angle of view θa corresponds to the second angle of view 31 in the upper diagram of FIG. 15. As described above, the first area 201a is an area with high resolution and low distortion, and the second area 201b is an area with low resolution and high distortion.

The ratio θa/θmax of the half angle of view θa to the maximum half angle of view Omax is desirably equal to or more than 0.15 and equal to or less than 0.35, and more desirably equal to or greater than 0.16 and equal to or smaller than 0.25. For example, in each of the above-described examples, since the maximum half angle of view θmax is 60°, the value of the half angle of view θa is desirably equal to or greater than 9.0° and equal to or smaller than 21.0°, and more desirably equal to or greater than 9.6° and equal to or smaller than 15.0°.

The optical system 201 is configured such that the projection characteristic y(θ) in the first area 201a is different from f×θ (equidistant projection method) and is also different from the projection characteristic in the second area 201b. In this case, it is desirable that the projection characteristic y(θ) of the optical system 201 satisfy the following inequality (9):

$$1. < f \times sin ( θ max ) / y ( θ max ) \leq 1.90 \qquad ( 9 )$$

Satisfying inequality (9) reduces the resolution in the second area 201b, thus achieving a wide angle of view of the optical system 201. Further, the resolution in the first area 201a can be made higher than that in the central area of a general fisheye lens that employs the orthogonal projection method (y(θ)=f×sinθ). If the lower limit of inequality (9) is not met, the resolution in the first area 201a may become lower than that of a fisheye lens of the orthogonal projection method, or the maximum image height may become larger, which undesirably leads to upsizing of the optical system. If the upper limit of inequality (9) is exceeded, the resolution in the first area 201a may become too high, which undesirably makes it difficult to achieve a wide angle of view equivalent to that of a fisheye lens of the orthogonal projection method, or undesirably makes it difficult to maintain favorable optical performance.

It is further desirable to satisfy the following inequality (9a), and it is yet further desirable to satisfy the following inequality (9b).

$$1. < f \times sin ( θmax ) / y ( θ max ) \leq 1 \text{.80} \qquad ( 9 a )$$

$$1. < f \times sin ( θmax ) / y ( θ max ) \leq 1.70 \qquad ( 9 b )$$

As described above, the optical system 201 exhibits low distortion and high resolution in the first area 201a, so that high-definition images are obtained as compared with the second area 201b. Therefore, setting the first area 201a (first angle of view 30) to the focus area for the user 40 makes it possible to obtain excellent visibility. For example, if the imaging device 20 is arranged at the rear part of the movable apparatus 10 as illustrated in the upper part of FIG. 15, displaying an image corresponding to the first angle of view 30 on the electronic rearview mirror allows the user 40 to feel a natural sense of perspective when gazing at a rear vehicle or the like. On the other hand, the second area 201b (second angle of view 31) corresponds to a wide angle of view including the first angle of view 30. Therefore, when the movable apparatus 10 is reversing, for example, displaying an image corresponding to the second angle of view 31 on the in-vehicle display can assist the user 40 in driving.

FIG. 16 is a functional block diagram illustrating a configuration example of an in-vehicle system 2 according to the present exemplary embodiment. The in-vehicle system 2 displays to the user 40 an image obtained by the imaging device 20 installed at a rear part of the movable apparatus 10. The in-vehicle system 2 has the imaging device 20, a processing device 220, and a display device (display unit) 230. As described above, the imaging device 20 has the optical system 201 and the imaging unit 210. The imaging unit 210 includes an imaging element such as a CCD sensor or a CMOS sensor, and generates imaging data by photoelectrically converting an optical image formed by the optical system 201, and outputs the imaging data to the processing device 220.

The processing device 220 includes an image processing unit 221, a display angle of view determination unit 224 (determination unit), a user setting change unit 226 (first change unit), a rear vehicle distance detection unit 223 (first detection unit), a reverse gear detection unit 225 (second detection unit), and a display angle of view change unit 222 (second change unit). The processing device 220 is a computer such as a central processing unit (CPU) microcomputer, and functions as a control unit that controls the operation of each component based on computer programs. At least one component in the processing device 220 may be implemented by hardware such as an application specific integrated circuit (ASIC) or a programmable logic array (PLA).

The image processing unit 221 generates image data by performing image processing such as wide dynamic range (WDR) correction, gamma correction, look up table (LUT) processing, and distortion correction on the imaging data acquired from the imaging unit 210. The distortion correction is performed on at least the imaging data corresponding to the second area 201b. This makes it easier for the user 40 to see the image displayed on the display device 230, thus improving the rate of detection of a rear vehicle by the rear vehicle distance detection unit 223. The distortion correction may be omitted for the imaging data corresponding to the first area 201a. The image processing unit 221 performs the image processing as described above and outputs the generated image data to the display angle of view change unit 222 and the rear vehicle distance detection unit 223.

The rear vehicle distance detection unit 223 uses the image data output from the image processing unit 221 to obtain information about the distance to a rear vehicle seen in the image data corresponding to the range of the second angle of view 31 that does not include the first angle of view 30. For example, the rear vehicle distance detection unit 223 can detect a rear vehicle based on the image data corresponding to the second area 201b from the plurality of pieces of image data, and calculate the distance from the rear vehicle to the vehicle including the in-vehicle system 2, based on the change in the position or size of the detected rear vehicle. The rear vehicle distance detection unit 223 outputs information about the calculated distance to the display angle of view determination unit 224.

The rear vehicle distance detection unit 223 may further determine the vehicle type of a rear vehicle based on data of feature information such as the shapes and colors of vehicle types, which is output as a result of machine learning (deep learning) based on a large number of vehicle images. In this case, the rear vehicle distance detection unit 223 may output information about the vehicle type of the rear vehicle to the display angle of view determination unit 224. The reverse gear detection unit 225 detects whether the transmission of the movable apparatus 10 (the vehicle including the in-vehicle system 2) is in reverse gear, and outputs a result of the detection to the display angle of view determination unit 224.

The display angle of view determination unit 224 determines whether the angle of view (display angle of view) of an image to be displayed on the display device 230 is to be set to a first angle of view 30 or a second angle of view 31, based on the output from at least one of the rear vehicle distance detection unit 223 and the reverse gear detection unit 225. Then, the display angle of view determination unit 224 provides output to the display angle of view change unit 222 based on a result of the determination. For example, the display angle of view determination unit 224 may determine that the display angle of view is to be set to the second angle of view 31 if the distance value in the distance information is equal to or smaller than a certain threshold (for example, 3 m), and may determine that the display angle of view is to be set to the first angle of view 30 if the distance value exceeds the threshold value. Alternatively, the display angle of view determination unit 224 may determine that the display angle of view is to be set to the second angle of view 31 if the reverse gear detection unit 225 has notified that the transmission of the movable apparatus 10 is in reverse gear. In contrast, the display angle of view determination unit 224 may determine that the display angle of view is to be set to the first angle of view 30 if the transmission of the movable apparatus 10 is not in reverse gear.

With the transmission of the movable apparatus 10 in reverse gear, the display angle of view determination unit 224 may determine that the display angle of view is to be set to the second angle of view 31 irrespective of a result of the detection performed by the rear vehicle distance detection unit 223. With the transmission of the movable apparatus 10 not in reverse gear, the display angle of view determination unit 224 may determine that the display angle of view is to be determined according to a result of the detection performed by the rear vehicle distance detection unit 223. In addition, the display angle of view determination unit 224 may change the determination criterion for changing the angle of view according to the vehicle type of the movable apparatus 10 by receiving vehicle type information from the rear vehicle distance detection unit 223. For example, if the movable apparatus 10 is a large vehicle such as a truck, the braking distance is longer than that for a regular car. This it is desirable to set the above-described threshold longer than that for a regular car (for example, 10 m).

The user setting change unit 226 allows the user 40 to change the determination criterion for determining whether to change the display angle of view to the second angle of view 31 in the display angle of view determination unit 224. The determination criterion set (changed) by the user 40 is input from the user setting change unit 226 to the display angle of view determination unit 224.

The display angle of view change unit 222 generates a display image to be displayed on the display device 230 according to the result of the determination performed by the display angle of view determination unit 224. For example, if the display angle of view determination unit 224 determines that the angle of view is to be set to the first angle of view 30, the display angle of view change unit 222 extracts a rectangular narrow-angle image (first image) from the image data corresponding to the first angle of view 30, and outputs it to the display device 230. If there is a rear vehicle that satisfies a predetermined condition in the image data corresponding to the second angle of view 31, the display angle of view change unit 222 outputs an image including the rear vehicle (second image) to the display device 230. The second image may include an image corresponding to the first area 201a. The display angle of view change unit 222 functions as a display control unit that performs display control to switch between a first display state in which the display device 230 displays the first image and a second display state in which the display device 230 displays the second image.

The image extraction by the display angle of view change unit 222 is executed by storing the image data output from the image processing unit 221 in a storage unit (memory) such as a RAM, and reading out the image for extraction from the storage unit. The area corresponding to the first image in the image data is a rectangular area in the first angle of view 30 corresponding to the first area 201a. The area corresponding to the second image in the image data is a rectangular area including the rear vehicle in the second angle of view 31 corresponding to the second area 201b.

The display device 230 includes a display unit such as a liquid crystal display or an organic electroluminescence (EL) display, and displays the display image output from the display angle of view change unit 222. For example, the display device 230 includes a first display unit that is an electronic rearview mirror arranged above the windshield (front glass) of the movable apparatus 10, and a second display unit that is an operation panel (monitor) arranged below the windshield of the movable apparatus 10. According to this configuration, the first image and the second image generated from the above-described image data can be displayed on the first display unit and the second display unit, respectively. The first display unit may include a semi-transparent mirror so as to be used as a mirror when not used as a display, for example. The second display unit may also serve as a display of a navigation system or an audio system, for example.

The movable apparatus 10 is not limited to a vehicle such as an automobile, and may be a movable body such as a ship, an airplane, an industrial robot, or a drone. The in-vehicle system 2 according to the present exemplary embodiment is used to present an image to the user 40, and may also be used for driving assistance such as cruise control (including full-speed following function) and automatic driving. Further, the in-vehicle system 2 is not limited to a movable apparatus and can be applied to various devices that use object recognition such as an intelligent transport system (ITS).

### Modifications

While an exemplary embodiment and examples of the present invention have been described above, the present invention is not limited to these exemplary embodiment and examples, and various combinations, modifications, and alterations are possible within the scope of the gist of the present invention.

For example, the optical systems according to the above-described examples are intended for use in the visible range and are configured to perform suitable aberration correction in the entire visible range. Alternatively, the wavelength range in which to perform aberration correction may be changed as necessary. For example, each optical system may be configured to perform aberration correction only in a specific wavelength range in the visible range, or may be configured to perform aberration correction in the infrared wavelength range outside the visible range.

In the above-described in-vehicle system 2, the imaging device 20 may be a distance measuring device as described above. In this case, the in-vehicle system 2 may include a determination unit that determines the possibility of a collision with an object based on information about the distance to the object acquired by the imaging device 20. In addition, the imaging device 20 may be a stereo camera having two imaging units 210. In this case, even if no imaging surface phase difference sensor is used, two pieces of image data can be simultaneously acquired by the synchronized imaging units, and the two pieces of image data can be used to perform processing similar to those described above. However, if the difference in imaging time between the imaging units is known, the synchronization of the imaging units may be omitted.

The above-described imaging device 20 may be configured such that the resolution in the second angle of view (second area) is higher than the resolution in the first angle of view (first area) as necessary. In other words, the number of pixels per unit angle of view in the first area may be smaller than the number of pixels per unit angle of view in the second area excluding the first area. This configuration is suitable for cases where it is desired to capture an enlarged image of a subject at the periphery of the angle of view rather than the center of the angle of view, such as when the imaging device 20 is provided at the position of a side view mirror of a vehicle.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

What is claimed is:

1. An optical system comprising, in this order from an object side: a first negative lens having a first aspheric surface, a second negative lens, a third negative lens that is a meniscus lens whose object-side surface is concave, a first positive lens, a cemented lens, and a final lens that is disposed closest to an image plane and includes an aspheric surface,
wherein an aperture stop is disposed between the third negative lens and the first positive lens, or between the first positive lens and the cemented lens, and
wherein the first aspheric surface has at least one inflection point in a cross-section including an optical axis.

2. The optical system according to claim 1, further comprising a first diaphragm configured to block part of an off-axial light beam.

3. The optical system according to claim 2, wherein the first diaphragm is disposed adjacent to the aperture stop.

4. The optical system according to claim 3, further comprising a second diaphragm, disposed on an image side of the aperture stop and the first diaphragm, configured to block part of an off-axial light beam.

5. The optical system according to claim 1, wherein the first negative lens has an object-side surface that is the first aspheric surface.

6. The optical system according to claim 5, wherein the first negative lens is disposed closest to an object.

7. The optical system according to claim 6, wherein a curvature of the first aspheric surface with respect to a radial position in a cross-section including the optical axis has a minimum value.

8. The optical system according to claim 7, wherein, in the first aspheric surface, the following inequality is satisfied:
$$0.5 \leq E \leq 0.80$$
where E represents a normalized distance from the optical axis to a position corresponding to the minimum value.

9. The optical system according to claim 1, wherein the following inequality is satisfied:
$$- 17.70 < f 1 / f < - 1.50$$
where f1 represents a focal length of the first negative lens, and f represents a focal length of the optical system.

10. The optical system according to claim 1, wherein the following inequality is satisfied:
$$- 22.50 < f 2 / f < - 0.70$$
where f2 represents a focal length of the second negative lens, and f represents a focal length of the optical system.

11. The optical system according to claim 1, wherein the following inequality is satisfied:
$$- 62.00 < f 3 / f < - 3.00$$
where f3 represents a focal length of the third negative lens, and f represents a focal length of the optical system.

12. The optical system according to claim 1, wherein the following inequality is satisfied:
$$0.7 < f 4 / f < 3.40$$
where f4 represents a focal length of the first positive lens, and f represents a focal length of the optical system.

13. The optical system according to claim 12, wherein the first positive lens includes an aspheric surface.

14. The optical system according to claim 1,
wherein the cemented lens is disposed on an image side of the aperture stop,
wherein the cemented lens includes a positive lens and a negative lens cemented to an object side of the positive lens, and
wherein the following inequality is satisfied:
$$0.3 < \vert fB / fA \vert < 3.2$$
$$0.2 < ν B / ν A < 0.8$$
where vA and fA represent an Abbe number and a focal length of the positive lens, respectively, and vB and fB represent an Abbe number and a focal length of the negative lens, respectively.

15. The optical system according to claim 1, wherein the following inequality is satisfied:
$$1.9 \vert f 9 / f \vert < 184.4$$
where f9 represents a focal length of the final lens, and f represents a focal length of the optical system.

16. The optical system according to claim 1, wherein the following inequality is satisfied:
$$1. < f \times sin ( θmax ) / y ( θ max ) \leq 1.90$$
where y(θ) represents a projection characteristic of the optical system representing a relationship between a half angle of view θ and an image height y, θmax represents a maximum half angle of view of the optical system, and f represents a focal length of the optical system.

17. An imaging device comprising:
the optical system according to claim 1; and
an imaging element configured to capture an image of an object via the optical system.

18. The imaging device according to claim 17,
wherein the imaging element includes a pixel with a plurality of light receiving units, and
wherein the plurality of light receiving units receives light beams each of which has passed through different pupil positions.

19. An in-vehicle system comprising:
the imaging device according to claim 17; and
a display device configured to display an image obtained based on an output of the imaging device.

20. A movable apparatus comprising the imaging device according to claim 17, and configured to move while holding the imaging device.
